(19) United States
(12) Patent Application Publication
(10) Pub. No.: US 2014/0097907 A1
(43) Pub. Date: Apr. 10, 2014

(54) MICRO CMOS POWER AMPLIFIER

(71) Applicants: Sung Man YOON, Yongin-si (KR); Jong Jin PARK, Pohang-si (KR)

(72) Inventors: Sung Man YOON, Yongin-si (KR); Jong Jin PARK, Pohang-si (KR)

(21) Appl. No.: 13/656,899

(22) Filed: Oct. 22, 2012

(30) Foreign Application Priority Data
Oct. 9, 2012 (KR) 10-2012-0112020

(51) Int. Cl. H03F 3/213

(52) U.S. Cl. CPC H03F 3/213
USPC 330/307

(57) ABSTRACT

The present invention relates to a micro CMOS power amplifier, in which an output transformer is configured as a substrate of a multilayer structure, and an amplifier circuit module is stacked on the output transformer. The micro CMOS power amplifier includes: an amplifier circuit module chip configured by modularizing circuits for amplifying power as a module; and an output transformer for outputting output of the amplifier circuit module chip to outside through a transformer circuit, in which the output transformer is implemented on a multilayer substrate, and the amplifier circuit module chip and the output transformer are configured as a stack.

According to the micro CMOS power amplifier of the present invention described above, an output transformer occupying a large space in a conventional power amplifier is configured as a multilayer substrate, and thus the chip size can be reduced within 50% without decreasing output power of the power amplifier.

### BACKGROUND OF THE INVENTION

1. Field of the Invention

The present invention relates to a micro CMOS power amplifier, in which an output transformer is configured as a substrate of a multilayer structure, and an amplifier circuit module is stacked on the output transformer.

2. Background of the Related Art

Generally, low power, low price, small size, high data rate, soft defined radio (SDR, a function of supporting multiple standards) and the like are items required for wireless terminals. From the viewpoint of power amplifier design, external surface mounting (SMT) components are developed so as to be embedded in a main RF chip if possible while reducing the number of the SMT components through a CMOS process, rather than a GaAS process, in order to accomplish the requirements on small size and low price. Currently, CMOS power amplifiers are considered as the biggest issue in the field of power amplifier (PA) research.

Since the CMOS power amplifiers can be implemented in a single chip of a Radio Frequency Integrated Circuit (RFIC) and are competitive in price, they are expected to be an amplifier of future wireless terminals. However, although a power amplifier having high linearity is required to design a transmitter of a high data rate, linearity of the CMOS power amplifier is unfortunately inferior to that of a GaAs power amplifier, and thus a transmitter structure for compensating the inferior linearity is required.

As communication systems evolve from 2 and 3 generations such as GSM, CDMA, WCDMA and the like to 3.5 and 4 generation schemes such as 3GPP LTE, Mobile WiMAX and the like, signals to be transmitted are complicated more and more. For the 3.5 and 4 generation communication systems, broad signal bands are required in communications of wireless terminals, and a further higher peak-to-average power ratio (PAPR) should be provided. Accordingly, next-generation power amplifiers for the wireless terminals are required to have high linearity and high efficiency.

Although chips designed as a linear CMOS power amplifier are developed and released in the market, they are still within the range of low and middle power. Amplifiers used for Bluetooth, ultra wideband (UWB) and the like are representative amplifiers of the lower power range. In addition, linear CMOS power amplifiers (PA) or the like for substituting GaAs power amplifiers used for existing WLAN are amplifiers of the middle power range.

However, linear CMOS power amplifiers of high power range are not commercialized until present. It is since that the linear CMOS power amplifiers of high power have a lot of limitations due to shortcomings of CMOS substrates compared with the GaAs substrates.

Since CMOS transistors have a characteristic of low breakdown voltage, it is not easy to develop a CMOS power amplifier generating high output power. Accordingly, they are disadvantageous in that battery use time is shortened due to low efficiency, which is one of the most important factors of a power amplifier for terminals. Such a disadvantage will be an obstacle to commercialization of power amplifiers using a CMOS process.

In order to solve the above problems, methods applying a cascode scheme and a voltage combining scheme of an output transformer are proposed as techniques for overcoming the characteristic of low breakdown voltage of the CMOS transistors.

Particularly, a differential structure using a transformer ideally solves source degeneration of a transistor caused by bonding wires and thus obtains a further higher gain.

However, a power amplifier should output a power higher than 30 dBm with respect to a power gain of 1 dB so as to be used as a 3G or 4G power amplifier for mobile communication. Although the CMOS power amplifier configures transistors as a two-stage cascode, a power amplifier of a single-ended structure is able to output only a power of about 28 dBm in maximum with respect to P1 dB. In addition, since it does not have a backside via, the source terminal is not grounded, and thus performance is severely degraded.

At this point, if a two-way transformer is used, a virtual ground (ground from the viewpoint of AC) of the source terminal can be rendered. In this case, although current is maintained as is, voltage swing is doubled, and thus output power is doubled (3 dB). Therefore, the power amplifier may output a power of 30 dBm. Accordingly, the transformer should be configured as described above in order to enhance output power of the CMOS power amplifier.

Meanwhile, the transformer can be configured inside or outside of a CMOS chip. A transformer implemented outside the CMOS chip is referred to as an ‘off chip transformer’, and a transformer implemented inside the CMOS chip is referred to as an ‘on chip transformer’.

FIG. 1a is a view showing a picture of a 3G CMOS power amplifier. Although a power amplifier of the on chip transformer scheme can be manufactured by configuring a transformer inside a CMOS chip as shown in FIG. 1a, the transformer occupies 50% of the entire size of the chip. If the size of the transformer is reduced, efficiency and maximum output power will be lowered, and thus the size of the transformer cannot be reduced.

In addition, since the transformer is configured inside the chip, power loss increases due to the silicon medium. Generally, a big loss is generated by the medium when matching is performed using lumped components, and the loss can be reduced greatly if a transformer of a slab inductor scheme with a small loss is used.

As shown in FIG. 1b, the off chip transformer scheme separates the CMOS power amplifier and the transformer. It is a structure that cannot be configured by stacking the CMOS chip on the transformer. An output transformer scheme implementing the transformer outside the CMOS chip may overcome the disadvantages of a silicon medium having a large power loss.

However, although the transformer configured as described above is absolutely needed in the CMOS power amplifier to increase output power, power loss occurs due to the structure and material of the transformer, and the transformer occupies almost 50% of the entire chip size of the power amplifier, and thus it is a big obstacle to commercialization of the power amplifier.

### SUMMARY OF THE INVENTION

Therefore, the present invention has been made in view of the above problems, and it is an object of the present invention to provide a micro CMOS power amplifier, in which an output transformer is configured as a substrate of a multilayer structure, and an amplifier circuit module is stacked on the output transformer.

To accomplish the above object, according to one aspect of the present invention, there is provided a micro CMOS power amplifier including: an amplifier circuit module chip configured by modularizing circuits for amplifying power as a module; and an output transformer for outputting output of the amplifier circuit module chip to outside through a transformer circuit, in which the output transformer is implemented on a multilayer substrate, and the amplifier circuit module chip and the output transformer are configured as a stack.

In addition, in the micro CMOS power amplifier, the output transformer forms a primary winding and a secondary winding on different layers, and the layers are stacked so that the primary and secondary windings are overlapped to face each other.

In addition, in the micro CMOS power amplifier, the amplifier circuit module chip is implemented as a CMOS chip.

In addition, in the micro CMOS power amplifier, the output transformer includes: a second layer formed with a primary winding pattern; a first layer formed with a first input terminal pattern and a primary winding connection pattern, in which the primary winding connection pattern is vertically connected to the primary winding pattern through a via hole; a third layer formed with a secondary winding pattern; and a fourth layer formed with a second input terminal pattern and an output terminal pattern, in which the second input terminal pattern is vertically connected to the first input terminal pattern through a via hole, and the output terminal pattern is vertically connected to the secondary winding pattern through a via hole, wherein the first to fourth layers are vertically arranged in order.

In addition, in the micro CMOS power amplifier, the amplifier circuit module chip is positioned to be stacked on the first layer, and external terminals of the amplifier circuit module chip are connected to the primary winding connection pattern or the first input terminal pattern through a wire.

In addition, in the micro CMOS power amplifier, both end units of the primary and secondary winding patterns are positioned in opposite directions.

In addition, in the micro CMOS power amplifier, the third layer is formed with an extension unit by extending a first end unit of the secondary winding pattern, and the second layer is formed with a condenser pattern facing the extension unit, in which the condenser pattern is connected to the a second end unit of the secondary winding pattern through a via hole.

### BRIEF DESCRIPTION OF THE DRAWINGS

FIG. 1 is a view showing an example of a CMOS power amplifier of a conventional on chip or off chip transformer scheme.

FIG. 2 is a circuit diagram showing a micro CMOS power amplifier according to a first embodiment of the invention.

FIG. 3 is a view schematically showing the configuration of a micro CMOS power amplifier according to a first embodiment of the invention.

FIG. 4 is a circuit diagram showing a power amplifier module according to a first embodiment of the invention.

FIG. 5 is a circuit diagram showing an output transformer according to a first embodiment of the invention.

FIG. 6 shows the configuration of each layer of an output transformer according to a first embodiment of the invention.

FIG. 7 is a view showing an example of combining a first layer of an output transformer with a power amplifier module according to a first embodiment of the invention.

FIG. 8 is a side view showing the configuration of a condenser of an output terminal according to a first embodiment of the invention.

FIG. 9 is a graph showing voltages and currents measured at the input and output terminals of a transformer according to a first embodiment of the invention.

FIG. 10 is a view showing frequency characteristics of a transformer according to a first embodiment of the invention.

FIG. 11 is a view showing input impedance of an output transformer according to a first embodiment of the invention.

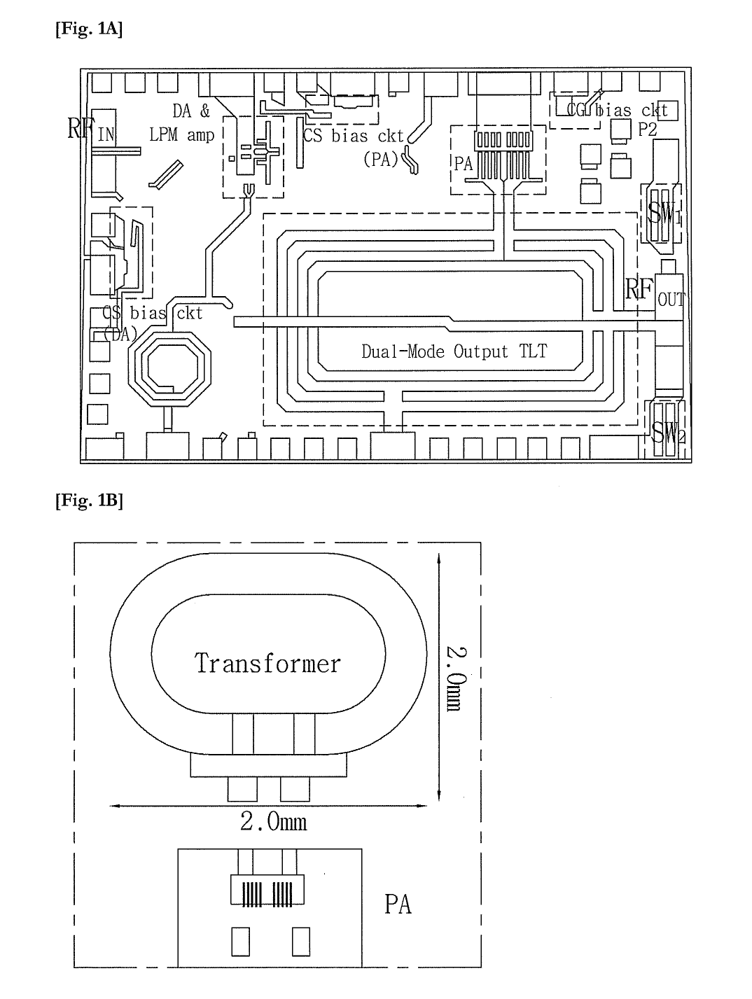

BRIEF DESCRIPTION OF THE DRAWINGS

| | |
|---|---|
| 1: Power amplifier | |
| 10: Input circuit | 20: Matching circuit |
| 30: Cascode circuit | 40: Output transformer circuit |
| 41: Primary winding | 42: Secondary winding |
| 50: Output | 60: Harmonic tuning circuit |
| 70: Bias circuit | 71: Bias voltage |

100: Amplifier circuit module chip
110: Input terminal

| | |
|---|---|
| 120: Connection terminal | 130: Bias voltage terminal |

140: Inductor ground terminal

| | |
|---|---|
| 200: Output transformer | 210: First layer |

219, 229, 239, 249: Dielectric layer
212: Signal connection pattern
213: Power connection pattern
214: Heat sink pattern
215: First Input terminal pattern
216: First bias terminal pattern
217: First power terminal pattern
218, 248: Ground pattern
221: Primary winding pattern
222: Both end unit

| | |
|---|---|
| 223: Center unit | 231: Secondary winding pattern |
| 232: Output end unit | 233: Ground end unit |
| 242: Output terminal pattern | 245: Second input terminal pattern |

246: Second bias terminal pattern
247: Second power terminal pattern
218, 228: Ground pattern

### DETAILED DESCRIPTION OF THE PREFERRED EMBODIMENT

The preferred embodiments of the invention will be hereafter described in detail, with reference to the accompanying drawings.

In addition, in the drawings illustrating the embodiments of the invention, elements having like functions will be denoted by like reference numerals and details thereon will not be repeated.

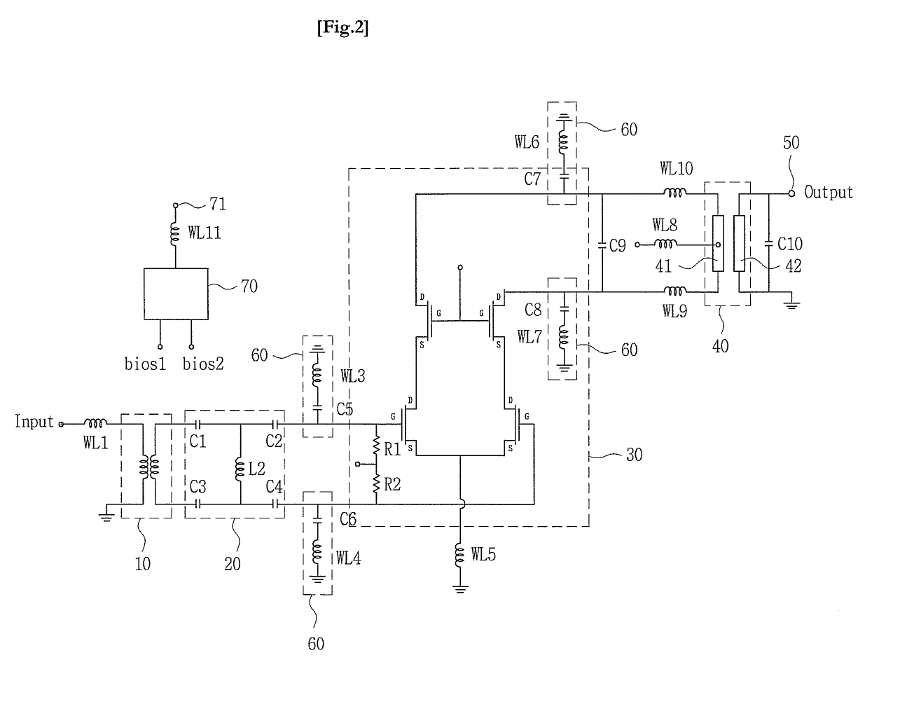

First, the configuration of the circuit of a micro CMOS power amplifier according to a first embodiment of the present invention is described with reference to FIG. 2.

As shown in FIG. 2, the circuit 1 of the micro CMOS power amplifier includes an input circuit 10, a matching circuit 20, a cascode circuit 30 and an output transformer circuit 40. In addition, a harmonic tuning circuit 60 is further included near the condenser of each partial circuit in order to solve the problems of vibration and heating of the condenser.

The input circuit 10 is a circuit for inputting signals, which is configured as an input balun transformer. The input balun transformer is a circuit for transforming balanced signals into unbalanced signals, which generates a differential signal from a single input signal.

The matching circuit 20 has a plurality of condensers C1, C2, C3 and C4 and an inductor L2, which is a general matching circuit for impedance matching of the input terminal in order to transmit a signal with least power loss.

The cascode circuit 30 is configured as a differential cascode circuit in order to increase output voltage without increasing breakdown voltage. This is a circuit for solving the problem of limiting maximum output power due to low breakdown voltage of a CMOS circuit. The differential cascode structure may increase voltage swing and breakdown voltage, compared with a single-ended structure. In addition, since via ground is not allowed in the CMOS process, ground is generally implemented using wire bonding. However, since the differential structure has a virtual AC ground at the source terminal of a transistor, the inductor effect can be reduced using the wire bonding. In addition, since the differential structure is a symmetrical structure and thus does not have harmonic waves of even numbers, harmonic components can be further decreased compared with the single-ended structure.

The output transformer circuit 40 is a circuit for stably amplifying output power by being electrically separated from the output 50, and it includes a primary winding 41 at the cascade circuit 30 terminal and a secondary winding 42 at the output 50 terminal.

In addition, the bias circuit 70 is a circuit for supplying bias voltage to a transistor circuit used in the cascade circuit 30, and it receives the bias voltage from outside.

Meanwhile, inductors WL1 to WL9 of the harmonic tuning circuit 60 or the like are implemented through wire bonding when the power amplifier 1 is configured. This will be described below in further detail.

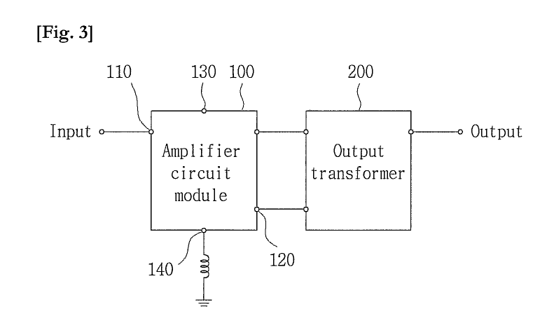

Next, the configuration of a micro CMOS power amplifier according to a first embodiment of the present invention is described with reference to FIG. 3.

As shown in FIG. 3, the micro CMOS power amplifier 1 according to a first embodiment of the present invention includes an amplifier circuit module chip 100 and an output transformer 200.

The amplifier circuit module chip 100 modularizes circuits for amplifying power (hereinafter, referred to as an amplifier circuit) as one module and configures the circuit as a substrate or a chip. Preferably, the amplifier circuit module chip 100 is configured as a CMOS circuit and manufactured as a chip.

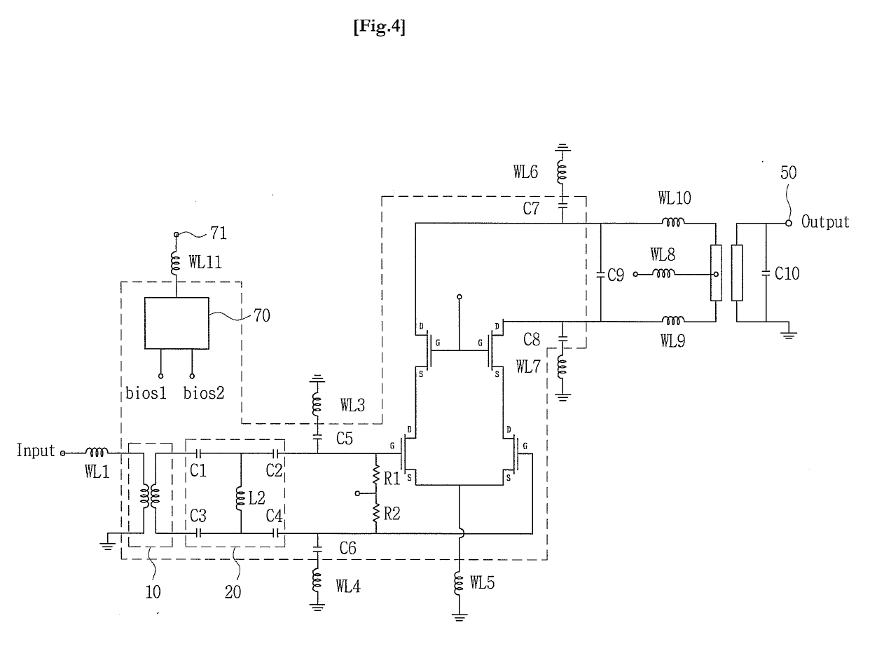

As shown in FIG. 4, the amplifier circuit module chip 100 includes major circuits for amplifying power, such as the input circuit 10, the matching circuit 20, the cascade circuit 30 and the bias circuit 70.

In addition, external terminals of the amplifier circuit module chip 100 include an input terminal 110, connection terminals 120, a bias voltage terminal 130 and an inductor ground terminal 140. The input terminal 110 is a terminal for receiving input signals at the input circuit 10, and the connection terminals 120 are terminals for outputting amplified signals, which are connected to the primary winding 41 of the output transformer circuit 40.

The bias voltage terminal 130 is a terminal for applying bias voltage of the bias circuit 70, and the inductor ground terminal 140 is a terminal for configuring inductors grounded through wire bonding. As shown in FIG. 4, the inductor ground terminal 140 includes terminals for inductors WL3, WL4, WL5, WL6 and WL7.

In the output transformer 200, the output transformer circuit 40 is implemented on a multilayer substrate such as low temperature co-fired ceramics (LTCC), and the layers are electrically connected through via holes.

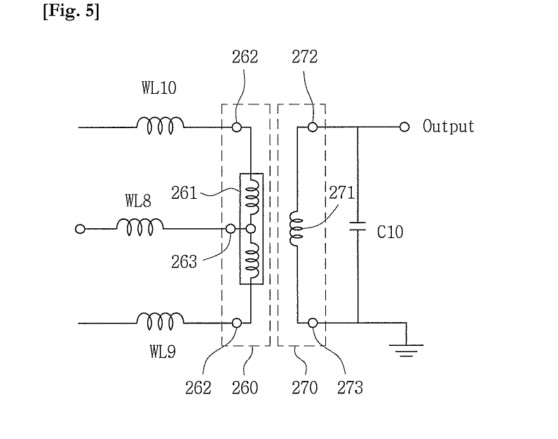

Before describing the configuration of the output transformer 200, the circuit of the output transformer 200 is described in further detail with reference to FIG. 5. FIG. 5 is a view showing the circuit of the output transformer 200, which is an enlarged view of the output transformer circuit 40 of FIG. 2.

As shown in FIG. 5, the output transformer 200 includes a primary winding unit 260 and a secondary winding unit 270. The primary winding unit 260 includes a first coil 261, two signal terminals 262 connected to both ends of the first coil 261, and a power terminal 263 connected to the center of the first coil 261. The secondary winding unit 270 includes a second coil 271, an output unit terminal 272 and a ground unit terminal 273, and the output unit terminal 272 and the ground unit terminal 273 are connected to both ends of the second coil 271. Meanwhile, a condenser C10 is provided between the output unit terminal 272 and the ground unit terminal 273.

Hereinafter, the multilayer structure of the output transformer 200 is described in further detail.

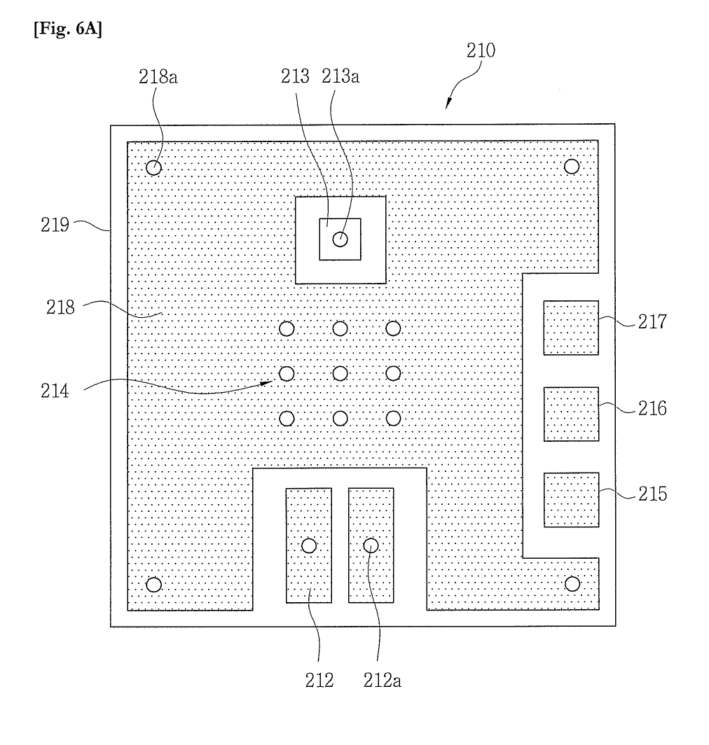

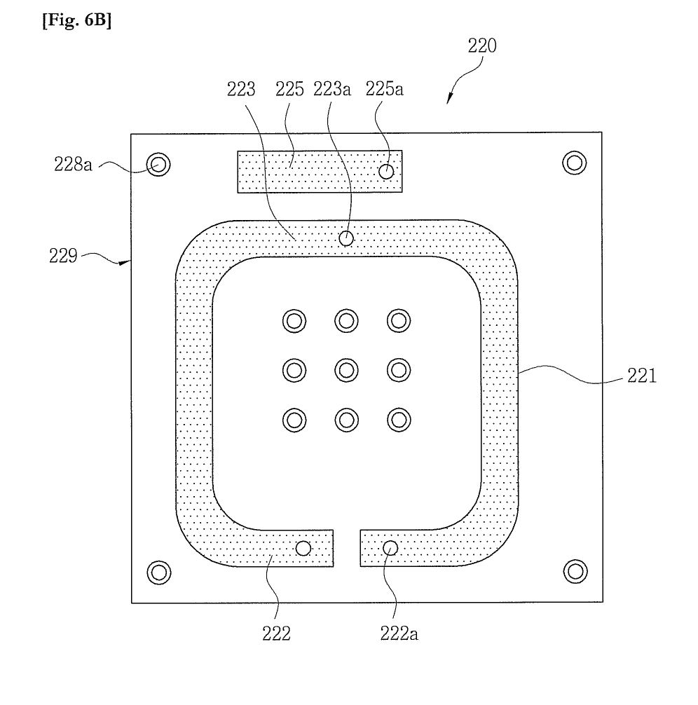

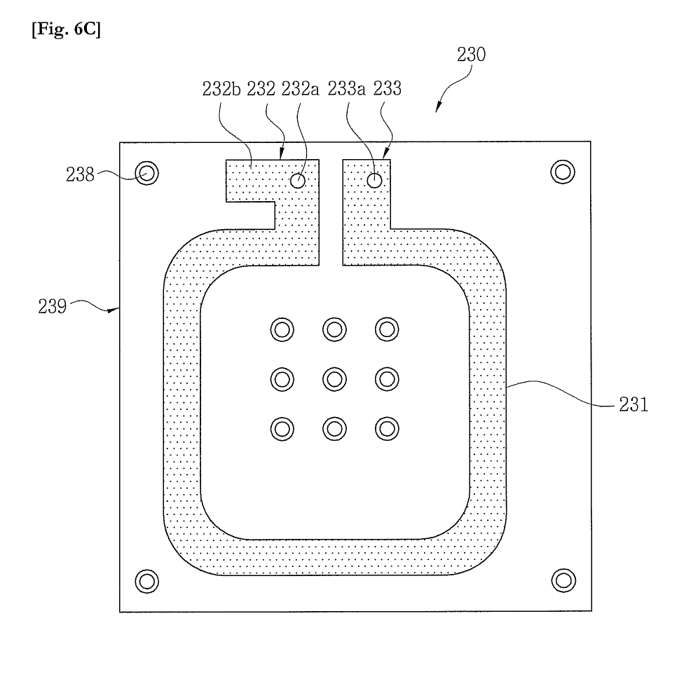

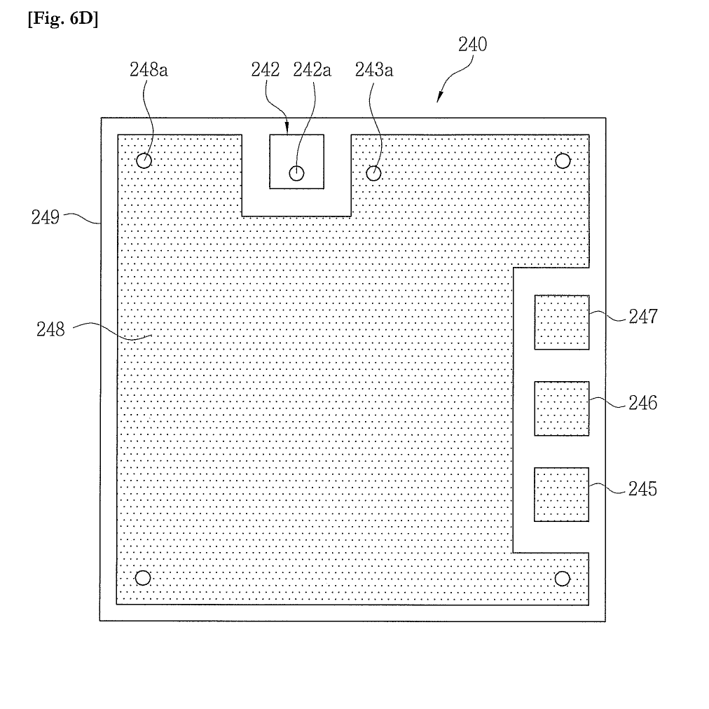

Next, the multilayer substrate structure of the output transformer 200 of the micro CMOS power amplifier 1 according to a first embodiment of the present invention is described with reference to FIG. 6. FIGS. 6a to 6d are plan views of a first layer, a second layer, a third layer and a fourth layer of the output transformer 200.

As shown in FIG. 6, the output transformer 200 has four layers of the first layer 210, the second layer 220, the third layer 230 and the fourth layer 240, and the four layers are vertically arranged in order. That is, the first layer 210 is arranged on the top, and the other layers are stacked under the first layer 210 in order of the second layer 220, the third layer 230 and the fourth layer 240.

In each of the layers 210 to 240, a copper foil layer is stacked on a dielectric layer 219, 229, 239 and 249, and a pattern is formed by etching parts of the copper foil layer. Hereinafter, the patterns formed on the layers are described by separating the layers into the first and second layers 210 and 220 and the third and fourth layers 230 and 240.

First, the first and second layers 210 and 220 are described.

The first and second layers 210 and 220 are layers which form the circuit of the primary winding unit 260 of the output transformer 200 shown in FIG. 5.

A primary winding pattern 221 constituting the primary winding unit 260 is formed on the second layer 220. The primary winding pattern 221 is formed as a conductive pattern, which is a conductive loop connected in series around the center of the substrate. The conductive loop is not formed as a closed loop, but a portion of the loop is disconnected. The disconnected portion of the conductive loop becomes both end parts (i.e., both end units) 222 of the primary winding pattern 221.

Via holes 222a are formed at both end units 222 of the primary winding pattern 221, and a via hole 223a is also formed at the center unit 223 of the primary winding pattern 221. The via holes 222a formed at both end units function as the signal terminals 262 of the primary winding unit, and the via hole 223a formed at the center unit functions as the power terminal 263.

In addition, a condenser pattern 225 is formed near the center unit 223 of the primary winding pattern, and a via hole 225a is formed inside the condenser pattern 225. The condenser pattern 225 is a pattern for implementing the condenser C10 connected to the secondary winding unit 270. The function of the condenser pattern 225 will be described in further detail when the third layer is described.

On the other hand, patterns for connecting to the terminals of the primary winding unit 210 and patterns for connecting to the external terminals of the amplifier are formed on the first layer 210. In addition, a ground pattern 218 is formed in the other areas.

The patterns connected to the terminals of the primary winding unit 210 include signal connection patterns 212 and a power connection pattern 213. Via holes 212a and 213a are formed in the signal connection patterns 212 and the power connection pattern 213, respectively.

The signal connection patterns 212 are formed at the positions of the both end units 222 of the primary winding pattern of the first layer 220, and the power connection pattern 213 is formed at the position of the center unit 223 of the primary winding pattern. Accordingly, the via holes 212a of the signal connection patterns are vertically connected to the via holes 222a of the both end units of the primary winding pattern, and the via hole 213a of the power connection pattern is vertically connected to the via hole 223a of the center unit of the primary winding pattern and electrically communicates with the via hole 223a of the center unit.

Accordingly, the signal connection patterns 212 function as the signal terminals 262 of the primary winding unit 270 respectively, and the power connection pattern 213 functions as the power terminal 263.

Next, the patterns connected to the external terminals of the amplifier include a first input terminal pattern 215, a first bias terminal pattern 216 and a first power terminal pattern 217.

The first input terminal pattern 215 is a conductive pattern for receiving external signals, and the first bias terminal pattern 216 is a conductive pattern for receiving power applied to the bias circuit. The first power terminal pattern 217 is a conductive pattern for receiving main power. The first input terminal pattern 215, the first bias terminal pattern 216 and the first power terminal pattern 217 are preferably formed on one side of the first layer 210.

On the other hand, on the first layer 210, the ground pattern 218 is formed in the areas other than the patterned areas, and at least one via hole 218a is formed in the ground pattern 218. The via hole 218a of the ground pattern is electrically connected to a ground pattern 248 of the fourth layer 240 and functions as ground.

In addition, a heat sink pattern 214 is preferably formed near the center of the first layer 210. Particularly, the heat sink pattern 214 is formed at the position of the amplifier circuit module chip 100 stacked on the first layer 210. Since the amplifier circuit module chip 100 is an integrated circuit and may emit large amounts of heat, the heat sink pattern 214 is formed as a pattern for dissipating the heat.

Meanwhile, on the second layer 220, via penetration holes 228a, through which via holes pass through, are formed at the positions the same as those of the via holes 218a and 248a so that the via holes 218a of the ground pattern may pass through and connect to the via holes 248a of the pattern ground.

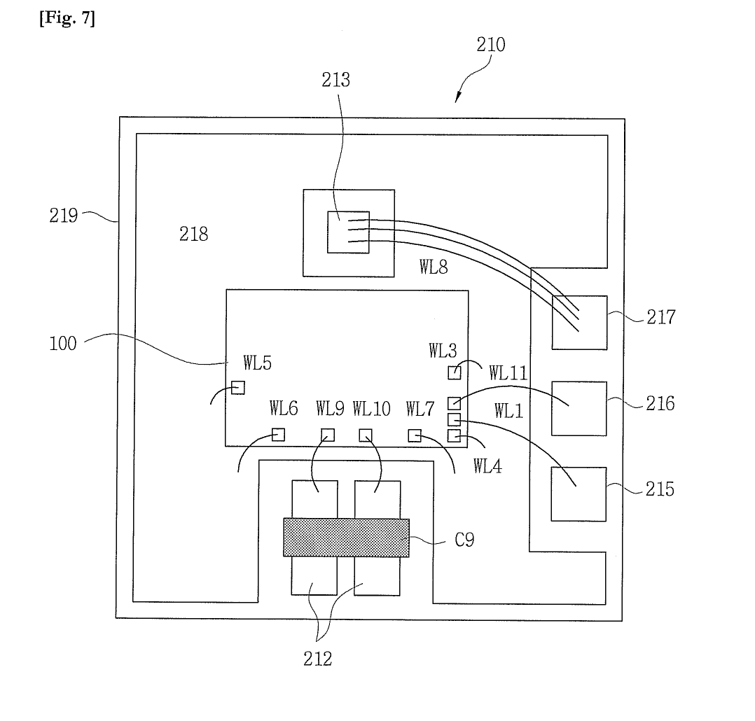

An embodiment of stacking the amplifier circuit module chip 100 on the first layer 210 is described with reference to FIG. 7.

As shown in FIG. 7, the external terminals formed in the amplifier circuit module chip 100 are electrically connected to the patterns on the first layer 210 through wires.

Specifically, the input terminal 110 WL1 of the amplifier circuit module chip 100 is connected to the first input terminal pattern 215 through a wire, and the bias voltage terminal 130 WL11 is connected to the first bias terminal pattern 216. In addition, the connection terminals 120 WL9/WL10 of the amplifier circuit module chip 100 are connected to the signal connection patterns 212 and, in the end, connected to the primary winding pattern 221 through the via holes 212a and 222a.

The inductor ground terminals 140 WL3, WL4, WL5, WL6 and W17 of the amplifier circuit module chip 100 are bonded to the ground pattern 218 through wires. That is, an inductor ground function is implemented through wire bonding.

Meanwhile, the power connection pattern 213 is coupled to a main power pattern 217 through a wire. In the end, the main power pattern 217 is connected to the center unit 223 of the primary winding pattern 221 through the via holes 213a and 223a.

Next, the third and fourth layers 230 and 240 are described.

The third and fourth layers 230 and 240 are layers which form the circuit of the secondary winding unit 270 of the output transformer 200 shown in FIG. 5.

A secondary winding pattern 231 constituting the secondary winding unit 270 is formed on third layer 230. The secondary winding pattern 231 is formed as a conductive pattern, which is a conductive loop connected in series around the center of the substrate. The conductive loop is not formed as a closed loop, but a portion of the loop is disconnected. The disconnected portion of the conductive loop becomes both end parts (i.e., both end units) 232 and 233 of the secondary winding pattern 231.

At this point, the conductive loop is preferably formed to face the primary winding pattern 221. However, the both end units 232 and 233 of the secondary winding pattern 231 are preferably positioned in a direction opposite to the positions of the both end units 222 of the primary winding pattern. Via holes 232a and 233a are formed at both end units 232 and 233 of the secondary winding pattern 231.

At this point, either of the both end units implements the output unit terminal 272 of the secondary winding unit 270, and the other end unit implements the ground unit terminal 273. For convenience, the former is referred to as an output end unit 232, and the latter is referred to as a ground end unit 233.

In addition, the conductive pattern of either the output end unit 232 or the ground end unit 233 is extended. For convenience, it is assumed that the output end unit 232 is extended, and the extended portion is referred to as an extension unit 232b.

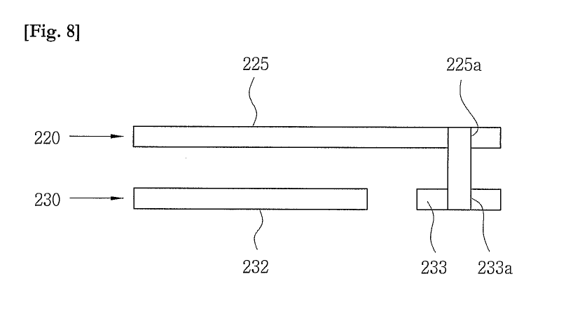

As shown in FIG. 8, the via hole 225a of the condenser pattern 225 of the second layer 220 is formed to vertically connect to a via hole 233a of the ground end unit 233 (i.e., the end unit that is not extended). That is, the condenser pattern 225 is connected to the ground end unit 233 through the via holes 225a and 233a.

In addition, the condenser pattern 225 is formed to be overlapped with the extension unit 232b in parallel. Accordingly, the extension unit 232b connected to the output end unit 232 is formed to face the condenser pattern 225 connected to the ground end unit 233 and functions as the condenser C10.

Meanwhile, patterns for connecting to the external terminals of the power amplifier 1 are formed on the fourth layer 210, and the ground pattern 248 is formed in the other areas.

An output terminal pattern 242, a second input terminal pattern 245, a second bias terminal pattern 246 and a second power terminal pattern 247 are formed as the patterns for connecting to the external terminals of the power amplifier 1.

The output terminal pattern 242 is formed at a position the same as that of the output end unit 232 of the third layer 230, and a via hole 232a is formed to vertically connect the output terminal pattern 242 to the output end unit 232. In addition, the second input terminal pattern 245, the second bias terminal pattern 246 and the second power terminal pattern 247 are formed at positions the same as those of the first input terminal pattern 215, the first bias terminal pattern 216 and the first power terminal pattern 217 respectively and connected through the via holes.

On the other hand, on the fourth layer 240, the ground pattern 248 is formed in the areas other than the patterned areas, and at least one via hole 248a is formed in the ground pattern 248 so as to be electrically connected to the ground pattern 218 of the first layer 210.

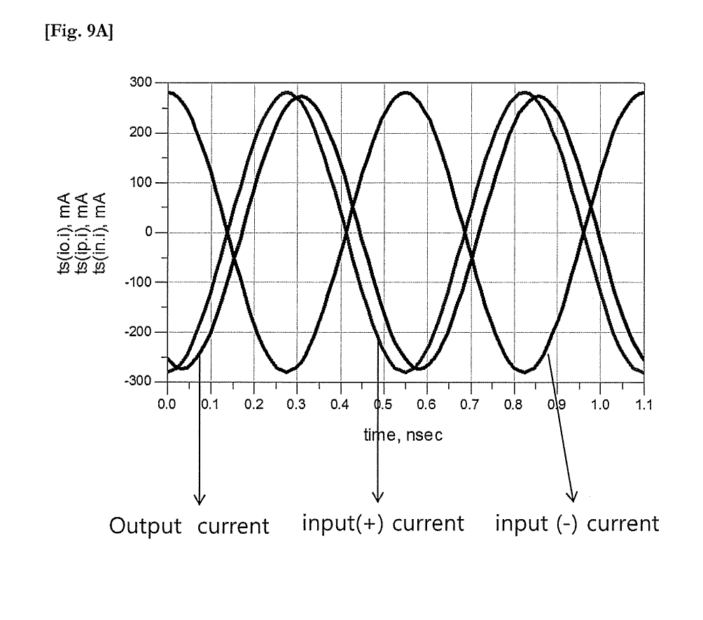

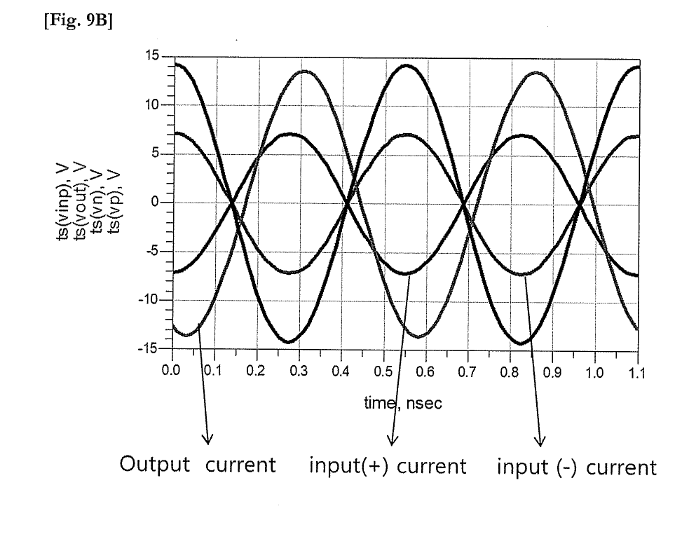

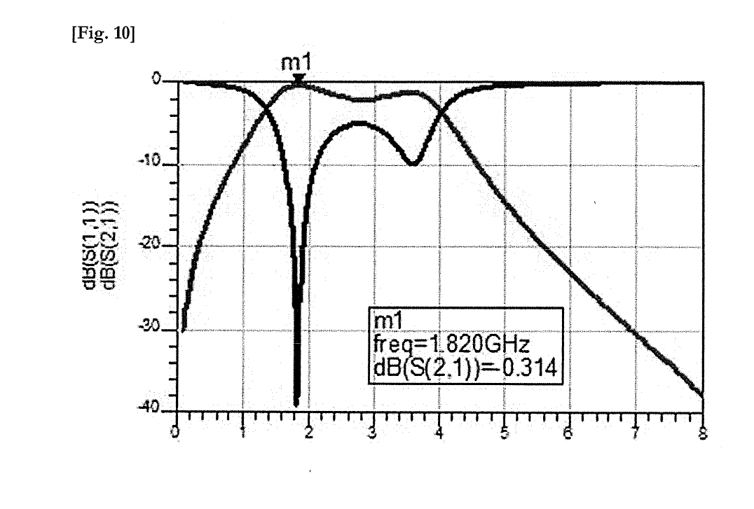

Next, the effects according to a first embodiment of the present invention will be described in further detail with reference to FIGS. 9 to 11.

As shown in FIGS. 5 and 6, currents and voltages respectively having a phase difference of 180 degrees are applied to the input of the primary winding. One of the input voltages having a phase difference of 180 degrees is inverted by 180 degrees, and thus the output voltage is doubled. Input and output currents are the same, and a doubled (3 dB) output current is ideally induced at the secondary winding.

As shown in FIG. 9, voltages applied to two input of a transformer are added to be a doubled voltage at the output, and thus output power is doubled at the final output terminal. Accordingly, a single CMOS power amplifier (PA) only outputs an output power of 27 dBm, and the other single CMOS PA outputs an output power of 27 dBm as a voltage having a phase difference of 180 degrees. This is referred to as a differential structure, and if the powers are combined using a transformer, an output power of 30 dBm can be outputted.

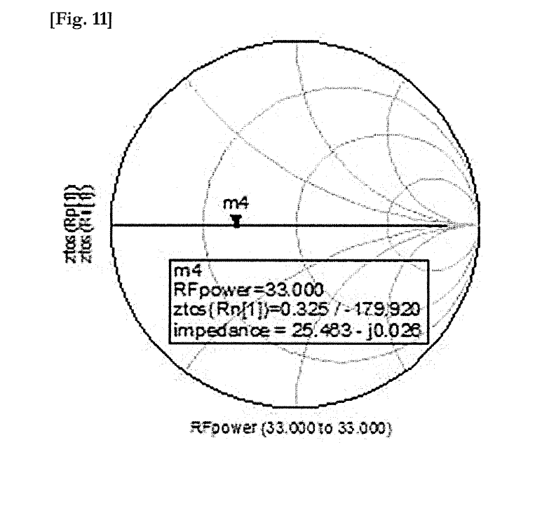

The transformer according to a first embodiment of the present invention actually generates a loss of 0.3 dB, and this is exceptionally excellent performance compared with a loss of 1 dB or higher of the on chip scheme according to a conventional technique. FIG. 11 shows input impedance of 25 ohm, which is only a half of 50 ohm.

According to the micro CMOS power amplifier of the present invention described above, an output transformer occupying a large space in a conventional power amplifier is configured as a multilayer substrate, and thus the chip size can be reduced within 50% without decreasing output power of the power amplifier.

While the present invention has been described with reference to the particular illustrative embodiments, it is not to be restricted by the embodiments but only by the appended claims. It is to be appreciated that those skilled in the art can change or modify the embodiments without departing from the scope and spirit of the present invention.

What is claimed is:

1. A micro CMOS power amplifier comprising:
an amplifier circuit module chip configured by modularizing circuits for amplifying power as a module; and
an output transformer for outputting output of the amplifier circuit module chip to outside through a transformer circuit, wherein
the output transformer is implemented on a multilayer substrate, and the amplifier circuit module chip and the output transformer are configured as a stack.

2. The amplifier according to claim 1, wherein the output transformer forms a primary winding and a secondary winding on different layers, and the layers are stacked so that the primary and secondary windings are overlapped to face each other.

3. The amplifier according to claim 1, wherein the amplifier circuit module chip is implemented as a CMOS chip.

3. The amplifier according to claim 1, wherein the output transformer includes:
a second layer formed with a primary winding pattern;
a first layer formed with a first input terminal pattern and a primary winding connection pattern, in which the primary winding connection pattern is vertically connected to the primary winding pattern through a via hole;
a third layer formed with a secondary winding pattern; and
a fourth layer formed with a second input terminal pattern and an output terminal pattern, in which the second input terminal pattern is vertically connected to the first input terminal pattern through a via hole, and the output terminal pattern is vertically connected to the secondary winding pattern through a via hole, wherein the first to fourth layers are vertically arranged in order.

5. The amplifier according to claim 4, wherein the amplifier circuit module chip is positioned to be stacked on the first layer, and external terminals of the amplifier circuit module chip are connected to the primary winding connection pattern or the first input terminal pattern through a wire.

6. The amplifier according to claim 4, wherein both end units of the primary and secondary winding patterns are positioned in opposite directions.

7. The amplifier according to claim 4, wherein the third layer is formed with an extension unit by extending a first end unit of the secondary winding pattern, and the second layer is formed with a condenser pattern facing the extension unit, wherein the condenser pattern is connected to the a second end unit of the secondary winding pattern through a via hole.
